(19) United States
(12) Patent Application Publication
(10) Pub. No.: US 2026/0180539 A1
(43) Pub. Date: Jun. 25, 2026

(54) Inductor Assembly

(71) Applicant: SUMIDA CORPORATION, Tokyo (JP)

(72) Inventor: Satoshi MINAMIDATE, Natori City (JP)

(21) Appl. No.: 19/539,323

(22) Filed: Feb. 13, 2026

Related U.S. Application Data
(63) Continuation of application No. PCT/JP2023/030101, filed on Aug. 22, 2023.

(51) Int. Cl. H03H 7/01

(52) U.S. Cl. CPC H03H 7/1775

(57) ABSTRACT

An inductor assembly is provided. Each of a pair of first terminals has a mounting portion and an erected portion. The mounting portion extends along a bottom surface of the inductor assembly. The erected portion is erected relative to the mounting portion. Each of a pair of second terminals has a mounting portion and an erected portion. The mounting portion extends along the bottom surface of the inductor assembly and the erected portion is erected relative to the mounting portion. The erected portion of one first terminal and the erected portion of one second terminal are formed on a first side surface of the inductor assembly. The pair of first terminals and the pair of second terminals are not formed on a second side surface that differs from the first side surface in an inductor.

### CROSS REFERENCE TO RELATED APPLICATIONS

This application claims priority to PCT International Patent Application No. PCT/JP2023/030101, filed on Aug. 22, 2023, which is expressly incorporated herein by reference in its entirety.

### BACKGROUND

### Technical Field

The present invention relates to an inductor assembly.

### Related Art

Some inductor assemblies are formed of a plurality of inductors integrated together. For example, Chinese Utility Model Registration No. 210722692 Specification (Patent Document 1) discloses a dual inductor that integrates two inductors. In the dual inductor, a second core (21) that is a rectangular parallelepiped is stacked on a first core (11) that is a rectangular parallelepiped. A second terminal (22) extends from the second core (21) to the first core (11). The two inductors are stacked and integrated by fitting the second terminal (22) into a second recessed portion (112).

Chinese Utility Model Registration No. 207925264 Specification (Patent Document 2) will be described later.

However, in the dual inductor according to Patent Document 1, a first terminal (12) or the second terminal (22) is arranged on each of four side surfaces of the dual inductor. Therefore, when arranging a plurality of dual inductors side by side or when arranging the dual inductor side by side with another component, sufficient clearance must be maintained between the dual inductors or between the dual inductor and the other component to ensure necessary insulation distance. Accordingly, a problem of requiring a mounting substrate with a larger area arises.

The present invention has been made in view of the problems described above and an object thereof is to provide an inductor assembly that enables space-saving on a mounting substrate.

### SUMMARY

An inductor assembly according to the present invention is an inductor assembly including a first core which encloses a first coil and a second core which is different from the first core and which encloses a second coil, wherein the second core is arranged above the first core, the inductor assembly has a plurality of side surfaces, each of the plurality of side surfaces in the inductor assembly includes a side surface of the first core and a side surface of the second core, each of a pair of first terminals electrically connected to the first coil protrudes from a side surface of the first core and has a mounting portion which extends along a bottom surface of the inductor assembly and an erected portion which is erected relative to the mounting portion, each of a pair of second terminals electrically connected to the second coil protrudes from a side surface of the second core and has a mounting portion which extends along the bottom surface and an erected portion which is erected relative to the mounting portion, the erected portion of one of the first terminals and the erected portion of one of the second terminals are formed on a first side surface among the side surfaces of the inductor assembly, and the pair of first terminals and the pair of second terminals are not formed on a second side surface of the inductor assembly which differs from the first side surface.

The inductor assembly has the second side surface on which the first terminals and the second terminals are not formed.

### Effect of the Invention

According to the inductor assembly of the present invention, the second side surface of the inductor assembly can be positioned in close proximity to another inductor assembly or another component (collectively referred to as another component or the like) when arranging the inductor assembly and the other component or the like on a mounting substrate. In this case, since the first terminals and the second terminals are not formed on the second side surface, the inductor assembly and the other component or the like can be arranged by bringing the second side surface sufficiently close to the other component or the like. Accordingly, space-saving on the mounting substrate can be realized.

### BRIEF DESCRIPTION OF THE DRAWINGS

The object described above as well as other objects, features, and advantages will be further clarified by the preferred embodiments described below and the following accompanying drawings, in which:

FIG. 1 is a perspective view showing an example of an inductor assembly according to a first embodiment of the present invention.

FIG. 2 is an exploded perspective view of the inductor assembly according to the first embodiment.

FIG. 3 is an exploded view and a perspective bottom view of the inductor assembly according to the first embodiment.

FIG. 4 is a top view of the inductor assembly according to the first embodiment.

FIG. 5 is a front view of the inductor assembly according to the first embodiment.

FIG. 6 is a right view of the inductor assembly according to the first embodiment.

FIG. 7 is a bottom view of the inductor assembly according to the first embodiment.

FIG. 8A is an enlarged view of an example of a second terminal in FIG. 5.

FIG. 8B is an enlarged view of another example of the second terminal in FIG. 5.

### DETAILED DESCRIPTION

Various constituent elements of an inductor assembly according to the present invention need not be individually independent entities. A plurality of constituent elements may be formed as a single member, a single constituent element may be formed by a plurality of members, a given constituent element may constitute a part of another constituent element, a part of a given constituent element and a part of another constituent element may overlap with each other, and the like.

In addition, while a method of manufacturing an inductor assembly according to the present invention may be described using a plurality of sequentially described steps, the described sequence is not intended to limit a sequence or a timing of executing the plurality of steps. Therefore, when implementing the manufacturing method according to the present invention, the sequence of the plurality of steps may be changed to the extent that such a change does not interfere with contents and a part of or all of the timings at which the plurality of steps are executed may overlap with each other.

Hereinafter, embodiments of the present invention will be described based on the drawings. In the respective drawings, corresponding constituent elements will be denoted by common reference signs and redundant descriptions will not be repeated.

In the present embodiments, descriptions will be given by defining directions of front, rear, left, right, up and down as shown. However, the directions are merely set for the sake of convenience for explaining correspondence relationships among the constituent elements in a simple manner and are not intended to limit directions during manufacture or during use of products that implement the present invention. An up-down direction is a perpendicular direction relative to a mounting substrate when mounting an inductor assembly on the mounting substrate. A lower side (downward) in the up-down direction refers to a side of the mounting substrate relative to the inductor assembly when the inductor assembly is mounted on the mounting substrate. An upper side (upward) refers to an opposite side to the lower side in the up-down direction. The up-down direction may or may not coincide with a vertical direction. A front-rear direction and a left-right direction may be collectively referred to as a lateral direction. The lateral direction may or may not coincide with a horizontal direction.

Moreover, the term “flat surface” as used in the present invention means a shape having been physically formed with a flat surface as a goal and, obviously, the shape need not be geometrically perfectly flat.

### First Embodiment

### (Inductor Assembly)

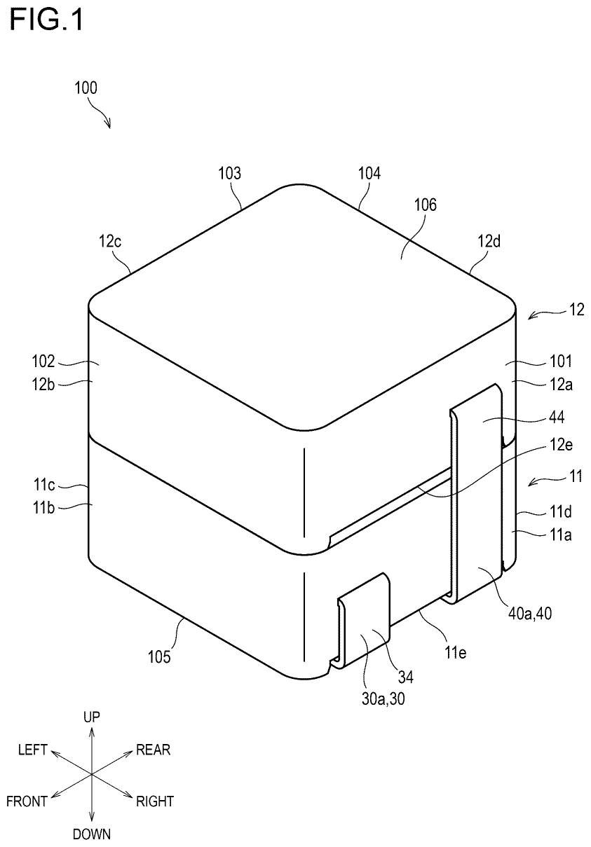

FIG. 1 is a perspective view showing an example of an inductor assembly 100 according to a first embodiment of the present invention.

First, an overview of the inductor assembly 100 according to the present embodiment will be described.

The inductor assembly 100 has a first core (first core 11) and a second core (second core 12). The first core encloses a first coil (first coil 21). The second core encloses a second coil (second coil 22). The second core is a core that differs from the first core. The second core is arranged above the first core.

The inductor assembly 100 has a plurality of side surfaces 101 to 104. Each of the plurality of side surfaces 101 to 104 in the inductor assembly includes side surfaces 11a to 11d of the first core 11 and side surfaces 12a to 12d of the second core 12.

A pair of first terminals 30 (30a, 30b) are electrically connected to the first coil 21. Each of the pair of first terminals 30 protrudes from a side surface (side surface 11a or side surface 11c) of the first core 11. In addition, each of the pair of first terminals 30 has a mounting portion 32 and an erected portion 34. The mounting portion 32 extends along a bottom surface 105 of the inductor assembly 100. The erected portion 34 is erected relative to the mounting portion 32.

A pair of second terminals 40 (40a, 40b) are electrically connected to the second coil 22. Each of the pair of second terminals 40 protrudes from a side surface (side surface 12a or side surface 12c) of the second core 12. Each of the pair of second terminals 40 has a mounting portion 42 and an erected portion 44. The mounting portion 42 extends along the bottom surface 105 of the inductor assembly 100 and the erected portion 44 is erected relative to the mounting portion 42.

The erected portion 34 of one first terminal 30a and the erected portion 44 of one second terminal 40a are formed on a first side surface 101 of the inductor assembly 100. The pair of first terminals 30a, 30b and the pair of second terminals 40a, 40b are not formed on a second side surface 102 that differs from the first side surface 101 in the inductor.

Forming both the erected portion of one first terminal and the erected portion of one second terminal on the first side surface enables the first terminal and the second terminal to be not formed on the second side surface in the inductor assembly according to the present embodiment. Accordingly, the second side surface of the inductor assembly can be positioned in close proximity to another inductor assembly or another component (collectively referred to as another component or the like) when arranging the inductor assembly and the other component or the like on a mounting substrate. In this case, since the first terminals and the second terminals are not formed on the second side surface, the inductor assembly and the other component or the like can be arranged by bringing the second side surface sufficiently close to the other component or the like. Accordingly, space-saving on the mounting substrate can be realized.

Note that in the inductor assembly 100 according to the present embodiment, the base (5) described in Patent Document 2 may not be required. Patent Document 2 discloses an inductor assembly in which two cores (stainless steel alloy powder blocks (3)) are arranged side by side. The base (5) covers top surfaces of the two cores. The base (5) is useful for attracting the inductor assembly to a mounter when mounting the inductor assembly onto the mounting substrate. In addition, the base (5) is useful for integrating the two cores. In the present embodiment, the first core 11 and the second core 12 are arranged in the up-down direction. In addition, a top surface 106 of the inductor assembly 100 is a top surface of the second core 12 and has a predetermined area. Therefore, the inductor assembly according to the present embodiment can attract the top surface 106 with a mounter. Furthermore, a second terminal 40 that extends from an upper second core 12 in the present embodiment fits with a terminal recessed portion 11e below the first core 11. The second terminal 40 combines and integrates the second core 12 and the first core 11.

Next, the inductor assembly 100 according to the present embodiment will be described in detail.

The inductor assembly 100 is an electronic component including a plurality of (two or more) inductors. An inductor is a single element including at least one coil and at least one core. The electronic component is incorporated into a part of an electronic circuit and forms a part of electrical equipment. The inductor assembly 100 according to the present embodiment includes two or more inductors and does not include other elements (transformer, antenna, and the like). While the inductor assembly 100 according to the present embodiment includes two inductors, the inductor assembly 100 may include three or more inductors.

In addition, the two or more inductors in the inductor assembly 100 are preferably integrated. In this case, the two or more inductors being integrated means that the inductors are configured to be inseparable by being coupled to each other or the like. For example, in the present embodiment, the first core 11 (first inductor) and the second core 12 (second inductor) are coupled to each other by having the second terminal 40 fit into a terminal recessed portion 11e formed on the bottom surface 105 of the first core 11. Alternatively, the two inductors may be grasped by another member. In this manner, the two inductors may be configured to be inseparable due to a mechanical structure. Alternatively, the two inductors may be configured to be inseparable by adhesion using an adhesive or the like. However, the two or more inductors being integrated does not include the two inductors being joined to the mounting substrate, respectively, in such a manner that the inductors cannot be further separated from each other.

The inductor assembly 100 has the first core 11 and the second core 12 as cores. The first core 11 is a core in the first inductor and the second core 12 is a core in the second inductor.

In the present embodiment, the first core 11 and the second core 12 are separate members that are separated from each other. In the present embodiment, as described later, the first core 11 and the second core 12 may be fixed to each other by an adhesive or the like; however, the first core 11 and the second core 12 are formed as separate bodies to such an extent that the two can be easily separated from each other, for example, by breaking an adhesive portion.

Each core is a magnetic member constituted of a magnetic material. Examples of the magnetic material include ferrite. In the present embodiment, since the core surrounds a coil (to be described later) and also penetrates into a radial interior of the coil, the core forms a closed loop as a whole. More specifically, the core according to the present embodiment is integrally formed by placing the coil and terminals (first terminal 30 and second terminal 40) in a mold and pouring resin containing a magnetic material such as ferrite into the mold. In other words, the first inductor and the second inductor in the inductor assembly 100 according to the present embodiment are molded coils, respectively. Instead of the present embodiment, the core may be constituted of a plurality of components.

The core according to the present embodiment has a flat, approximately rectangular parallelepiped shape. A shape of a bottom surface of the core is approximately square. The bottom surface of the first core 11 and the bottom surface of the second core 12 have approximately the same shapes and dimensions. The second core 12 is placed on the first core 11 so that the cores overlap with each other in a plan view. Due to the first core 11 and the second core 12 with approximately rectangular parallelepiped shapes being arranged in the up-down direction, the inductor assembly 100 has an approximately rectangular parallelepiped shape.

In the present embodiment, a top surface of the first core 11 and the second core 12 are bonded using an adhesive (not illustrated). Accordingly, the first core 11 and the second core 12 are prevented from shifting. The adhesive may or may not be arranged between a terminal recessed portion 12e (to be described later) of the second core 12 and the top surface of the first core 11. Instead of the present embodiment, the first core 11 and the second core 12 may simply be in contact (in abutment) with each other without being bonded by an adhesive. Engaging portions where the first core 11 and the second core 12 engage with each other may be provided to fix a relative positional relationship between the first core 11 and the second core 12. Specifically, a recessed portion or a protruding portion may be provided on the top surface of the first core 11 and the bottom surface of the second core 12, respectively, and the recessed portion and the protruding portion may engage with each other.

Instead of the present embodiment, the inductor assembly 100, the first core 11, and the second core 12 need not have an approximately rectangular parallelepiped shape, respectively. For example, the inductor assembly 100, the first core 11, and the second core 12 may have a polygonal columnar shape that has a bottom surface of a non-quadrilateral shape.

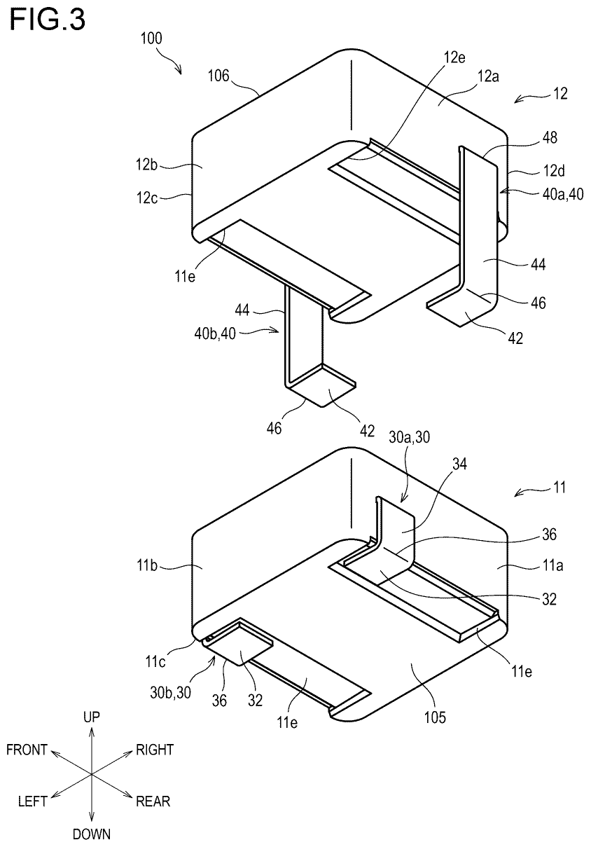

As illustrated in FIG. 3, terminal recessed portions 11e, 12e are formed on the bottom surfaces of the respective cores according to the present embodiment. The terminal recessed portions 11e, 12e are bottomed recessed portions which are recessed upward from the bottom surface of the cores. The terminal recessed portions 11e, 12e open downward and sideward (in the present embodiment, rightward or leftward).

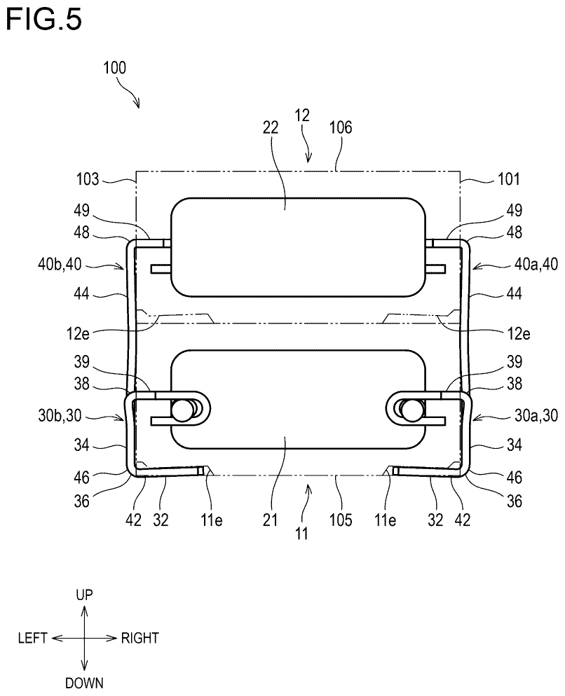

As illustrated in FIG. 5, ceiling surfaces (the bottom surfaces of the terminal recessed portions 11e, 12e, which are bottomed and recessed upward) of the terminal recessed portions 11e, 12e slope upward toward an interior of the inductor assembly 100.

As illustrated in FIG. 1, the first core 11 and the second core 12 has a plurality of side surfaces, respectively. The first core 11 has a plurality of side surfaces 11a, 11b, 11c, and 11d. The second core 12 has a plurality of side surfaces 12a, 12b, 12c, and 12d. One side surface of the first core 11 is arranged so as to adjoin one side surface of the second core 12. In this case, surfaces being arranged so as to adjoin each other means the surfaces are arranged with respective edges adjacent to each other and positioned approximately on a same plane. The surfaces may be partially separated from each other. In addition, one side surface among the side surfaces 11a to 11d of the first core 11 and one side surface among the side surfaces 12a to 12d of the second core 12 each form one of side surfaces 101 to 104 of the inductor assembly 100. Specifically, the side surface 11a of the first core 11 and the side surface 12a of the second core 12 form the first side surface 101 of the inductor assembly 100. In a similar manner, the side surface lib of the first core 11 and the side surface 12b of the second core 12 form the second side surface 102 of the inductor assembly 100. The side surface 11c of the first core 11 and the side surface 12c of the second core 12 form a third side surface 103 of the inductor assembly 100. The side surface 11d of the first core 11 and the side surface 12d of the second core 12 form a fourth side surface 104 of the inductor assembly 100.

The inductor assembly 100 has the first coil 21 and the second coil 22 as coils. The first coil 21 is a coil in the first inductor and the second coil 22 is a coil in the second inductor.

Each coil is formed by winding a coil wire. While the coil wire is wound with the up-down direction as a winding axis direction in the present embodiment, the winding axis direction is not limited thereto. The coil wire may be wound with the left-right direction or the front-rear direction as the winding axis direction. The coil wire is formed of a conductive material (for example, a metal such as copper). The coil wire may be a round wire with a circular cross-section or a flat wire with a flat cross-section (for example, quadrilateral or elliptical).

Both end portions of the coil wire are extracted from a winding portion of the coil. The end portions of the coil wire may be extracted from the winding portion near a center of the winding portion of the coil in a thickness direction (up-down direction) or extracted from the winding portion on an upper side or a lower side in the thickness direction. In addition, both end portions of the coil wire may be extracted from the winding portion at a same height (position in the up-down direction) or extracted from the winding portion at different heights. For example, both end portions may be extracted from the winding portion near the center of the winding portion in the thickness direction. Alternatively, one end portion may be extracted from the winding portion on an upper side of the winding portion in the thickness direction and the other end portion may be extracted from the winding portion on a lower side of the winding portion in the thickness direction.

Furthermore, both end portions of the coil wire are extracted from the winding portion at two positions that sandwich the winding portion in the present embodiment, respectively. Both end portions of the coil wire are not limited thereto and may be extracted from any positions.

In the present embodiment, a winding portion of the first coil 21 and a winding portion of the second coil 22 are arranged spaced apart from each other in an up-down direction. This is because the winding portion of the first coil 21 and the winding portion of the second coil 22 are disposed inside the first core 11 and the second core 12, respectively.

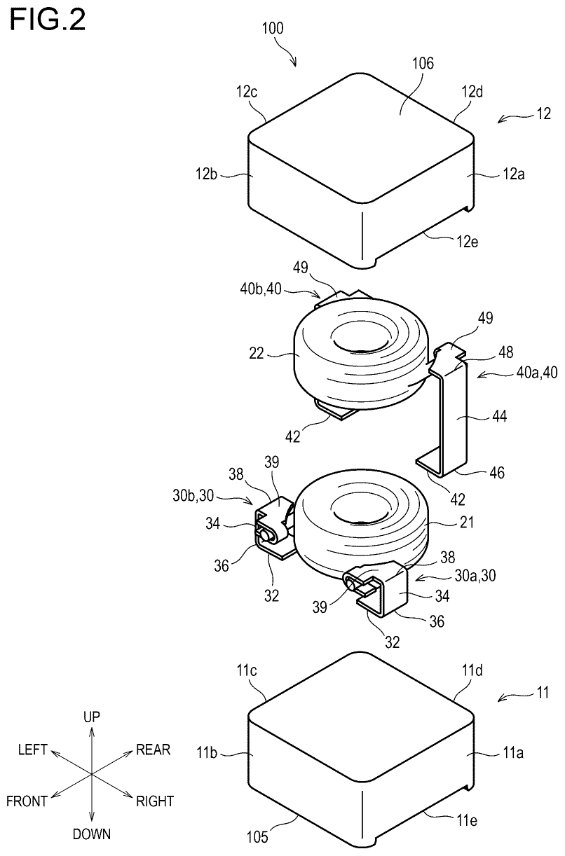

Each end portion of the coil wire is electrically connected to a terminal (first terminal 30 or second terminal 40). Specifically, end portions of the coil wire that forms the first coil 21 are electrically connected to the first terminals 30, and end portions of the coil wire that forms the second coil 22 are electrically connected to the second terminals 40. More specifically, as illustrated in FIGS. 2 and 5, the end portions of the terminals inserted into the core are bent into a U-shape. The end portions of the terminals grasp the end portions of the coil wire and sandwich the end portions of the coil wire in the up-down direction. The end portions of the coil wire and the end portions of the terminals are joined by a method such as laser welding or resistance welding. A mode of the conduction of the coil wire and the terminals is not limited to direct contact as described above. The coil wire and the terminals may be electrically connected to each other via another member. For example, the end portions of the coil wire may be connected to connection terminals that are separate members from the terminals and the coil wire and the terminals may be electrically connected via the connection terminals when the connection terminals and the terminals are connected. In addition, the coil wire and the terminals may be integrally formed from a same member.

In the present embodiment, the terminals are input/output terminals and each inductor is connected to another electronic component, an electronic device, and the like via the terminals.

The terminals are formed of a conductive member. Examples of the conductive member include metals such as copper. The terminals according to the present embodiment are formed by bending a plate-like conductive member.

The terminals according to the present embodiment have embedded portions 39, 49, erected portions 34, 44, and mounting portions 32, 42.

The embedded portion 39 is embedded in the first core 11 or the second core 12. The embedded portions 39, 49 are parts of the terminals that are embedded inside the core. In other words, parts of the terminals that continue from the embedded portions 39, 49 protrude sideward (in one of left-right directions) from the core. The embedded portion 39 is an end portion on a side of the terminal that is electrically connected to the coil wire and is also a base end portion. In a terminal, one end electrically connected to the coil wire will be referred to as a base end and another end on an opposite side to the one end will be referred to as a distal end. Instead of the present embodiment, all of the terminals may be arranged outside the core and the terminals may not have the embedded portions 39, 49.

The mounting portions 32, 42 are parts of the terminals and include a mounting surface that is in contact with the mounting substrate. The inductor assembly 100 is mounted by joining the mounting portions 32, 42 to the mounting substrate by soldering or the like. The mounting portions 32, 42 and the mounting surfaces extends along the bottom surface 105 of the inductor assembly (bottom surface of the first core 11). The mounting portions 32, 42 and the mounting surfaces extending along the bottom surface 105 of the inductor assembly 100 means that the mounting portions 32, 42 and the mounting surfaces are approximately parallel to the bottom surface 105 of the inductor assembly 100. In the present embodiment, as will be described later, terminals are bent inward in first bent portions 36, 46 and the mounting portions 32, 42 and the mounting surfaces closely extend along the bottom surface 105 of the inductor assembly 100. In this case, the mounting portions 32, 42 extend along a ceiling surface of the terminal recessed portion 11e. In other words, the mounting portions 32, 42 are approximately parallel to the ceiling surface of the terminal recessed portion 11e. Note that in the present embodiment, as will be described later, an inclination angle of the ceiling surface of the terminal recessed portion 11e and an inclination angle of the mounting portions 32, 42 differ from each other and are not completely parallel to each other. Instead of the present embodiment, the terminals may be bent outward in the first bent portions 36, 46 and the mounting portion 32 and the mounting surface may be arranged to the side of the inductor assembly 100 and extend along the bottom surface 105 of the inductor assembly 100.

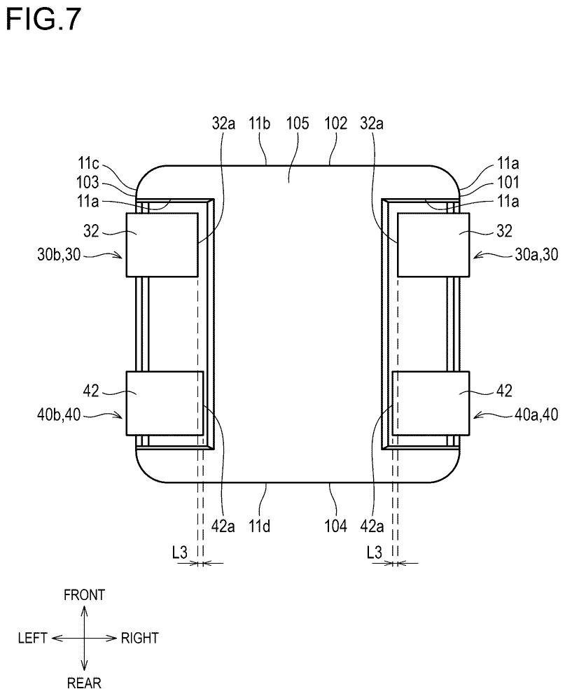

As illustrated in FIGS. 5 and 7, the mounting portions 32, 42 are arranged in the terminal recessed portion 11e of the first core 11. In the present embodiment, both the mounting portion 32 of the first terminal 30 and the mounting portion 42 of the second terminal 40 which are horizontally aligned are arranged in one terminal recessed portion 11e. Instead of the present embodiment, one or a plurality of terminal recessed portions 11e may be formed on the bottom surface of the core according to the number of terminals, and one or a plurality of mounting portions 32, 42 may be arranged in each terminal recessed portion 11e.

The erected portions 34, 44 are parts of the terminals and are erected relative to the mounting portions 32, 42. The erected portions 34, 44 are positioned between the embedded portion (base end portion) and the mounting portion (distal end portion). The erected portions 34, 44 being erected relative to the mounting portions 32, 42 means that the erected portions 34, 44 extend so as to intersect relative to the mounting portions 32, 42. More preferably, an extension direction of the erected portions 34, 44 includes a greater directional component perpendicular to an extension direction of the mounting portions 32, 42 than an extension direction component of the mounting portions 32, 42. Even more preferably, the extension direction of the erected portions 34, 44 is approximately the up-down direction. The erected portions 34, 44 extend along the side surfaces 101 to 104 of the inductor assembly 100. The erected portions 34, 44 may be in contact with (in abutment with or in pressurized contact with) or separated from the side surfaces 101 to 104 of the inductor assembly 100.

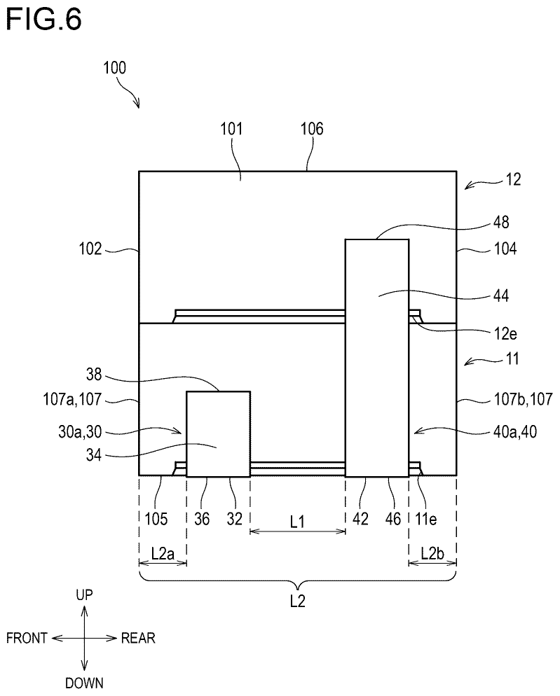

In addition, as illustrated in FIG. 6, the erected portions 34, 44 of each terminal is arranged outside in a lateral direction (front-rear direction) relative to a center of the inductor assembly 100 in the lateral direction when viewed opposing a plate surface (main surface) of the erected portions 34, 44 (when viewed in the left-right direction). Accordingly, a relative positional relationship between the first core 11 and the second core 12 is fixed. For example, the first core 11 is prevented from shifting so as to rotate with the up-down direction as a rotational axis relative to the second core 12.

The erected portions 34, 44 have an approximately linear shape that extends along the up-down direction.

As illustrated in FIG. 5, an upper part of the erected portion 44 of the second terminal 40 may be curved toward the cores (first core 11 and the second core 12) (so as to approach the side surfaces 11a, 11c of the first core 11 and the side surfaces 12a, 12c of the second core 12). In other words, the upper part of the erected portion 44 of the second terminal 40 may be recessed inward. Accordingly, the second terminal 40 can favorably hold the first core 11 and the second core 12. In the present embodiment, as a result of the erected portion 44 being curved, a part of the erected portion 44 is in close contact in a gap-less manner with the side surface of the core (side surfaces 11a, 11c of the first core 11 or side surfaces 12a, 12c of the second core 12). Alternatively, the erected portion 44 as a whole and the side surfaces of the core may be separated from each other.

Here, the upper part of the erected portion 44 of the second terminal 40 is a part arranged on an upper side relative to the first terminal 30 (in particular, a second bent portion 38 in the first terminal 30) in the second terminal 40. In other words, the upper part of the erected portion 44 of the second terminal 40 is a part that extends along a lower part of the side surfaces 12a, 12c (refer to FIG. 1) of the second core 12 and an upper part of the side surfaces 11a, 11c (refer to FIG. 1) of the first core 11 in the second terminal 40. In addition, while the upper part of the erected portion 44 of the second terminal 40 has a curved shape, the lower part (a part that extends along the lower part of the side surfaces 11a, 11c of the first core 11) and the first terminal 30 has an approximately linear shape or a curved shape that is closer to a linear shape. In other words, the upper part of the erected portion 44 of the second terminal 40 may be curved more than the lower parts of the first terminal 30 and the second terminal 40. Note that curved shape of the second terminal 40 is illustrated in an exaggerated manner for the sake of clarity in FIG. 5. The actual inductor assembly 100 may have a shape closer to a linear shape than the illustrated curved shape.

In the present embodiment, the second terminal 40 is bent approximately at a right angle in the second bent portion 48. Alternatively, the second terminal 40 is bent so as to protrude and bulge slightly outward in the second bent portion 48.

Alternatively, the first terminal 30 and the second terminal 40 may have approximately linear shapes as a whole.

As illustrated in FIG. 5, the terminals (first terminal 30 and second terminal 40) are bent so that the mounting portions 32, 42 are arranged below the inductor assembly 100 in the first bent portions 36, 46. The first bent portions 36, 46 are positioned between the erected portions 34, 44 and the mounting portions 32, 42. In other words, the terminals are bent inward from the erected portions 34, 44 to the mounting portions 32, 42 in the present embodiment. Inward refers to a direction toward inside the inductor assembly 100. In the present embodiment, the first bent portion 36, 46 is bent in a curved shape. Instead of the present embodiment, the first bent portion 36, 46 may be bent in an angular manner. The first bent portion 36, 46 are bent in a shape that conforms to the shape of corners formed by the side surfaces 101, 103 and the bottom surface 105 of the inductor assembly 100. Note that the terminal being bent includes not only the terminal being bent to form a corner but also the terminal being curved in an arc shape without having a distinct corner.

The first bent portions 36, 46 are parts in the terminal each having a smaller radius of curvature than the erected portions 34, 44 or the mounting portions 32, 42. Since the erected portions 34, 44 and the mounting portions 32, 42 substantially have an approximately linear shape, portion between the erected portions 34, 44 and the mounting portions 32, 42 and having a curved shape are the first bent portions 36, 46.

Each of the terminals (first terminal 30 and second terminal 40) is bent at second bent portions 38, 48. The second bent portions 38, 48 are positioned between the embedded portions 39, 49 and the erected portions 34, 44. In other words, in the present embodiment, the terminals are bent downward from the embedded portions 39, 49 to the erected portions 34, 44. In the present embodiment, the second bent portions 38, 48 are bent in a curved shape. Instead of the present embodiment, the second bent portions 38, 48 may be bent in an angular manner. In the present embodiment, the second bent portions 38, 48 are formed in the terminals so as to be bent immediately after protruding from the core (first core 11 or second core 12).

The second bent portions 38, 48 are parts in the terminal each having a smaller radius of curvature than the erected portions 34, 44 or the embedded portions 39, 49. Since the erected portions 34, 44 substantially have an approximately linear shape, portions between the base end portions of the cores which protrude from and are present outside the cores and the erected portions 34, 44 and having a curved shape are the second bent portions 38, 48.

As illustrated in FIG. 5 and described above, the erected portion 34 of one first terminal 30a and the erected portion 44 of one second terminal 40a are formed on the first side surface 101 (on a same side surface). Here, the erected portions 34, 44 being formed on the first side surface 101 means that the erected portions 34, 44 are arranged extending on a plane of the first side surface 101. The erected portions 34, 44 may be arranged on the first side surface 101 in contact with (in abutment with or in pressurized contact with) the first side surface 101 or may be arranged on the first side surface 101 while being separated from the first side surface 101. In addition, the erected portions 34, 44 are formed on a surface facing sideward among the surfaces of the inductor assembly 100. In the present embodiment, the side surfaces 101 to 104 which the erected portions 34, 44 extend along in the inductor assembly 100 are flat surfaces. In other words, among the side surfaces 101 to 104 which the erected portions 34, 44 extend along in the inductor assembly 100, parts covered by the erected portions 34, 44 are continuous with other parts. Instead of the present embodiment, a recessed groove extending in the up-down direction may be formed on the side surfaces 101 to 104 of the inductor assembly 100 and a least a part of the erected portions 34, 44 may be embedded in the recessed groove. In other words, the erected portions 34, 44 may be formed on a bottom surface of the recessed groove. The bottom surface of the recessed groove is also a part of the side surfaces 101 to 104 of the inductor assembly 100.

As illustrated in FIG. 6, the erected portion 34 of one first terminal 30a and the erected portion 44 of one second terminal 40a extend along one another. In other words, the one first terminal 30a and the one second terminal 40a both extend in approximately the same extension direction. In addition, the one first terminal 30a and the one second terminal 40a are arranged side by side in the front-rear direction.

On the other hand, a pair of first terminals 30a, 30b and a pair of second terminals 40a, 40b are not formed on the second side surface 102 among the side surfaces 101 to 104 of the inductor assembly 100 which differs from the first side surface 101. In other words, the pair of first terminals 30a, 30b and the pair of second terminals 40a, 40b are not formed on the second side surface 102. In other words, when viewed opposite the second side surface 102, the second side surface 102 as a whole is exposed from the pair of first terminals 30a, 30b and the pair of second terminals 40a, 40b.

While the second side surface 102 is a side surface adjacent to the side surface 101 in the present embodiment, the second side surface 102 is not limited thereto. The second side surface 102 may be a side surface not adjacent to the side surface 101. In the inductor assembly 100 according to the present embodiment which has four side surfaces 101 to 104, the second side surface 102 is a side surface that opposes the side surface 101 or a side surface that is adjacent to the side surface 101. For example, when the bottom surface of the inductor assembly 100 has a regular hexagon and the inductor assembly 100 has six side surfaces, the second side surface 102 is a side surface that is 180 degrees opposite the first side surface 101, a side surface that is 120 degrees opposite the first side surface 101, or a side surface that is adjacent to the first side surface 101. Preferably, the second side surface 102 is a side surface that is 180 degrees opposite to the first side surface 101 or a side surface that is 90 degrees opposite to the first side surface 101. Accordingly, the inductor assembly 100 can be arranged in close proximity to another component or the like arranged to the front or back or to the left or right of the inductor assembly 100.

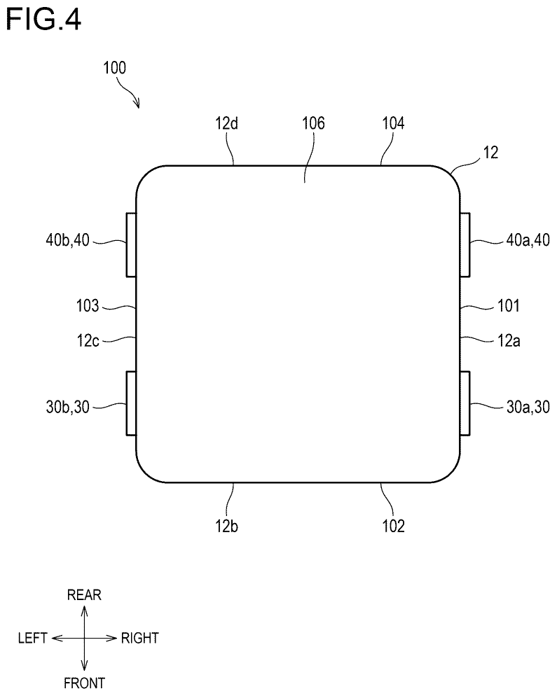

As illustrated in FIG. 4, another first terminal 30b and another second terminal 40b are formed on the third side surface 103. The third side surface 103 is one of the side surfaces of the inductor assembly 100. The third side surface 103 opposes the first side surface 101.

The pair of first terminals 30a, 30b and the pair of second terminals 40a, 40b are not formed on the fourth side surface 104. The fourth side surface 104 is one of the side surfaces of the inductor assembly 100. The fourth side surface 104 opposes the second side surface 102.

Accordingly, another component or the like can also be arranged in close proximity to the fourth side surface 104 that opposes the second side surface 102 in addition to in close proximity to the second side surface 102 and the mounting substrate can be utilized so as to achieve more space-saving.

In the present embodiment, the first side surface 101 and the third side surface 103 oppose each other by 180 degrees and the second side surface 102 and the fourth side surface 104 also oppose each other by 180 degrees. Instead of the present embodiment, the first side surface 101 and the third side surface 103 may oppose each other by 90 degrees and the second side surface 102 and the fourth side surface 104 may also oppose each other by 90 degrees. In other words, in the inductor assembly 100 that has a quadrangle bottom surface and four side surfaces, the first side surface 101 and the third side surface 103 may be adjacent side surfaces and the second side surface 102 and the fourth side surface 104 may also be adjacent side surfaces.

Furthermore, instead of the present embodiment, the erected portion 34 of the other first terminal 30b and the erected portion 44 of the other second terminal 40b may be formed on the first side surface 101 and the pair of first terminals 30a, 30b and the pair of second terminals 40a, 40b may not be formed on the third side surface 103 and the fourth side surface 104. In other words, all of the two erected portions 34 of the pair of first terminals 30a, 30b and the two erected portions 44 of the pair of second terminals 40a, 40b may be formed on the first side surface 101.

As illustrated in FIG. 4, on each of the first side surface 101 and the third side surface 103, the first terminals 30a, 30b and the second terminals 40a, 40b are arranged side by side in a predetermined arrangement direction (front-rear direction). Specifically, on the first side surface 101, the first terminal 30a and the second terminal 40a are arranged side by side in a predetermined arrangement direction, and on the third side surface 103, the first terminal 30b and the second terminal 40b are arranged side by side in the predetermined arrangement direction. Each of the one first terminal 30a and the other first terminal 30b is arranged on a same side (front side) in the arrangement direction (front-rear direction) relative to the one second terminal 40a or the other second terminal 40b. In other words, the one first terminal 30a is arranged on the front side in the front-rear direction relative to the one second terminal 40a, and the other first terminal 30b is also arranged on the front side in the front-rear direction relative to the other second terminal 40b.

Accordingly, the first terminal 30 and the second terminal 40 may be favorably mounted to the mounting substrate. The first terminal 30 and the second terminal 40 may have different shapes as will be described later, and the heights of the mounting portions 32, 42 may differ slightly between the first terminal 30 and the second terminal 40. In other words, there may be cases where a difference between a height of the mounting portion 32 of the first terminal 30 and a height of the mounting portion 42 of the second terminal 40 is greater than a difference in heights of the mounting portions 32 of the pair of first terminals 30a, 30b or a difference in heights of the mounting portions 42 of the pair of second terminals 40a, 40b. Arranging the first terminal 30a on the first side surface 101 and the first terminal 30b on the third side surface 103 on a same side (front side) as the second terminals 40a, 40b that are arranged side by side with respect to the first terminals 30a, 30b makes grounding of each terminal to the mounting substrate more favorable than a case where the first terminal 30a is arranged on a front side of the second terminal 40a and the first terminal 30b is arranged on a rear side of the second terminal 40b. Even if there is a significant difference in height between the mounting portions 32 of the first terminals 30a, 30b and the mounting portions 42 of the second terminals 40a, 40b, the inductor assembly 100 can still achieve favorable grounding of the four terminals to the mounting substrate by tilting slightly forward or rearward.

The predetermined arrangement direction in which the first terminal 30 and the second terminal 40 are arranged side by side is a lateral direction and, in particular, a direction along the first side surface 101 or the third side surface 103 (side surface which the first terminal 30 and the second terminal 40 extend along) in the lateral direction. Hereinafter, the predetermined arrangement direction of the first terminal 30 and the second terminal 40 arranged side by side with respect to the first terminal 30 may simply be referred to as an arrangement direction.

Each of the one first terminal 30a and the other first terminal 30b being arranged on a same side relative to the one second terminal 40a or the other second terminal 40b refers to the pair of first terminals 30a, 30b being arranged on a same side (front side) as the pair of second terminals 40a, 40b when viewed from the predetermined direction (for example, in a plan view).

In the present embodiment, the pair of first terminals 30a, 30b or the pair of second terminals 40a, 40b oppose each other. More specifically, when viewed from a lateral side (that is, when viewed from the left-right direction), a pair of the first terminals 30a, 30b or a pair of the second terminals 40a, 40b at least partially overlap each other (and, in the present embodiment, substantially entirely overlap each other).

As illustrated in FIG. 6, on the first side surface 101 or the third side surface 103, a central distance L1 is equal to or greater than an edge distance L2 (a sum of a first edge distance L2a and a second edge distance L2b). The edge distance L2 is the sum of the first edge distance L2a and the second edge distance L2b.

Accordingly, when two inductor assemblies 100 are arranged side by side, an insulation distance between respective terminals of the two inductor assemblies 100 is maintained while also maintaining an insulation distance between the first terminal 30 and the second terminal 40 arranged horizontally within the inductor assemblies 100. For example, when two inductor assemblies 100 are arrange in a same orientation in the front-rear direction, an insulation distance between the second terminal 40 of the front-side inductor assembly 100 and the first terminal 30 of the rear-side inductor assembly 100 (inter-inductor assembly insulation distance) is maintained while also maintaining an insulation distance between the first terminal 30 and the second terminal 40 in each inductor assembly 100 (intra-inductor assembly insulation distance). More specifically, the inter-inductor assembly distance includes the edge distance L2 and a width of a gap between inductor assemblies 100 to be described later. Therefore, making the central distance L1 equal to or greater than L2 enables the inter-inductor assembly distance and the intra-inductor assembly distance to be made approximately the same.

The central distance L1 refers to a distance between the first terminals 30a, 30b and the second terminals 40a, 40b arranged side by side in the arrangement direction on the first side surface 101 or the third side surface 103. That is, the central distance L1 is a distance between the first terminal 30a and the second terminal 40a that are arranged side by side in the arrangement direction on the first side surface 101, or a distance between the first terminal 30b and the second terminal 40b that are arranged side by side in the arrangement direction on the third side surface 103. Specifically, the central distance L1 is a shortest distance along a lateral direction (front-rear direction) between a side end surface of the first terminal 30a and a side end surface of the second terminal 40a on the first side surface 101 or between a side end surface of the first terminal 30b and a side end surface of the second terminal 40b on the third side surface 103.

The first edge distance L2a refers to a distance between a first end portion 107a and the first terminals 30a, 30b on the first side surface 101 or the third side surface 103. The first end portion 107a is an end portion 107 of the first side surface 101 or the third side surface 103 in the arrangement direction which is the end portion 107 in close proximity to the first terminals 30a, 30b on the first side surface 101 or the third side surface 103. In the present embodiment, the end portion 107 is an end portion in the front-rear direction of the first side surface 101 or the third side surface 103. Specifically, the end portion 107 on the first side surface 101 is a side that constitutes a boundary between the first side surface 101 and the second side surface 102 and a side that constitutes a boundary between the first side surface 101 and the fourth side surface 104. In addition, the end portion 107 on the third side surface 103 is a side that constitutes a boundary between the third side surface 103 and the second side surface 102 and a side that constitutes a boundary between the third side surface 103 and the fourth side surface 104. Among the end portions 107, the first end portion 107a on the first side surface 101 is a side that constitutes a boundary between the first side surface 101 and the second side surface 102 and the first end portion 107a on the third side surface 103 is a side that constitutes a boundary between the third side surface 103 and the second side surface 102. The distance between the first end portion 107a and the first terminals 30a, 30b is a shortest distance along the lateral direction (front-rear direction) between the first end portion 107a and the side end surfaces of the first terminals 30a, 30b.

The second edge distance L2b refers to a distance between a second end portion 107b and the second terminals 40a, 40b on the first side surface 101 or the third side surface 103. The second end portion 107b is an end portion 107 of the first side surface 101 or the third side surface 103 in the arrangement direction which is an end portion 107 in close proximity to the second terminals on the first side surface 101 or the third side surface 103. Specifically, the second end portion 107b on the first side surface 101 is a side that constitutes a boundary between the first side surface 101 and the fourth side surface 104 and the second end portion 107b on the third side surface 103 is a side that constitutes a boundary between the third side surface 103 and the fourth side surface 104. The distance between the second end portion 107b and the second terminals 40a, 40b is a shortest distance along the lateral direction (front-rear direction) between the second end portion 107b and the side end surfaces of the second terminals 40a, 40b.

The difference between the central distance L1 and the edge distance L2 is preferably smaller than a width dimension (dimension in the lateral direction and, in particular, the front-rear direction) of the first terminal 30 or the second terminal 40. Accordingly, the edge distance L2 is sufficiently secured and the insulation distance between adjacent inductor assemblies 100 is secured.

In addition, the first edge distance L2a and the second edge distance L2b are preferably equal. The first edge distance L2a and the second edge distance L2b being equal means that the first edge distance L2a is equal to or more than half of the second edge distance L2b and equal to or less than twice the second edge distance L2b.

In addition, the central distance L1 and the edge distance L2 may be equal. The central distance L1 and the edge distance L2 being equal means that the central distance L1 is equal to or more than half of the edge distance L2 and equal to or less than twice the edge distance L2. Instead of the present embodiment, the central distance L1 may be shorter than the edge distance L2.

As illustrated in FIG. 7, in a plan view, a distal end 42a of the mounting portion 42 of the second terminals 40a, 40b is arranged further inside the inductor assembly 100 than a distal end 32a of the mounting portion 32 of the first terminals 30a, 30b which are arranged side by side with respect to the second terminals 40a, 40b. Here, with respect to a set of the first terminal 30a, 30b and the second terminal 40a, 40b located on either the first side surface 101 or the third side surface 103, it is sufficient that the distal end 42a of the mounting portion 42 of the second terminal 40a, 40b is disposed closer to an inner side of the inductor assembly 100 than the distal end 32a of the mounting portion 32 of the first terminal 30a, 30b that is arranged side by side with the second terminal 40a, 40b. In FIG. 7, the first terminal 30 and the second terminal 40 are illustrated so as to further emphasize this configuration for the sake of convenience. In other words, a distal end distance L3 to be described later is shown larger than an actual distance.

The second terminal 40 is extended from the second core 12 and is bent so as to cradle the first core 11, and holds the first core 11 together with the second core 12. Due to the distal end 42a of the second terminal 40 being arranged further inside the inductor assembly 100 than the distal end 32a of the first terminal 30, the second terminal 40 can more favorably hold the first core 11.

In addition, since the second terminal 40 extends to a higher position than the first terminal 30, a load on a joint surface between the mounting portion 42 of the second terminal 40 and the mounting substrate tends to be greater than a load on a joint surface between the mounting portion 32 of the first terminal 30 and the mounting substrate. Arranging the distal end 42a of the second terminal 40 to be further inside in a plan view increases a mounting surface between the second terminal 40 and the mounting substrate. As a result, the second terminal 40 is more firmly joined to the mounting substrate, thereby improving durability against loads applied to the joining surface between the second terminal 40 and the mounting substrate.

The distal ends 32a, 42a of the mounting portions 32, 42 are ends on opposite sides to sides that continue to the erected portions 34, 44 in the mounting portions 32, 42. In other words, the distal ends 32a, 42a of the mounting portions 32, 42 are inside ends of the inductor assembly 100 in the mounting portions 32, 42 in a plan view.

The inside of the inductor assembly 100 when viewed from a predetermined direction refers to a direction from an outer edge of the inductor assembly 100 toward the center of the inductor assembly 100 when the inductor assembly 100 is viewed from the predetermined direction.

The distal end 42a of the one second terminal 40a is arranged to the left of the distal end 32a of the one first terminal 30a. In addition, the distal end 42a of the other second terminal 40b is arranged to the right of the distal end 32a of the other first terminal 30b. Accordingly, an area of the mounting portion 42 of the one second terminal 40a is larger than an area of the mounting portion 32 of the one first terminal 30a. In addition, an area of the mounting portion 42 of the other second terminal 40b is larger than an area of the mounting portion 32 of the other first terminal 30b. The areas of the mounting portions 32, 42 may be the areas of the mounting portions 32, 42 when opposing the mounting portions 32, 42 or areas in a bottom view of the mounting portions 32, 42.

In addition, the distal end 42a of the second terminal 40 is preferably arranged further inside the inductor assembly 100 than the distal end 32a of the first terminal 30 by a length equivalent to or greater than a thickness dimension of the first terminal 30 or the second terminal 40. In other words, a distance (distal end distance L3) between the distal end 42a of the second terminal 40 and the distal end 32a of the first terminal 30 in the extension direction (left-right direction) of the mounting portions 32, 42 is preferably equal to or greater than the thickness dimension of the first terminal 30 or the second terminal 40 (in particular, the mounting portions 32, 42 thereof). Accordingly, the area of the mounting portion 42 of the second terminal 40 can be sufficiently increased. Alternatively, in order to secure a larger area of the mounting portion 32 of the first terminal 30, the distal end 32a of the first terminal 30 may be arranged further inside the inductor assembly 100. In other words, the distal end 42a of the second terminal 40 may be arranged further inside the inductor assembly 100 than the distal end 32a of the first terminal 30 by a length equivalent to or less than a thickness dimension of the first terminal 30 or the second terminal 40. In other words, the distal end distance L3 may be set equal to or less than the thickness dimension of the first terminal 30 or the second terminal 40.

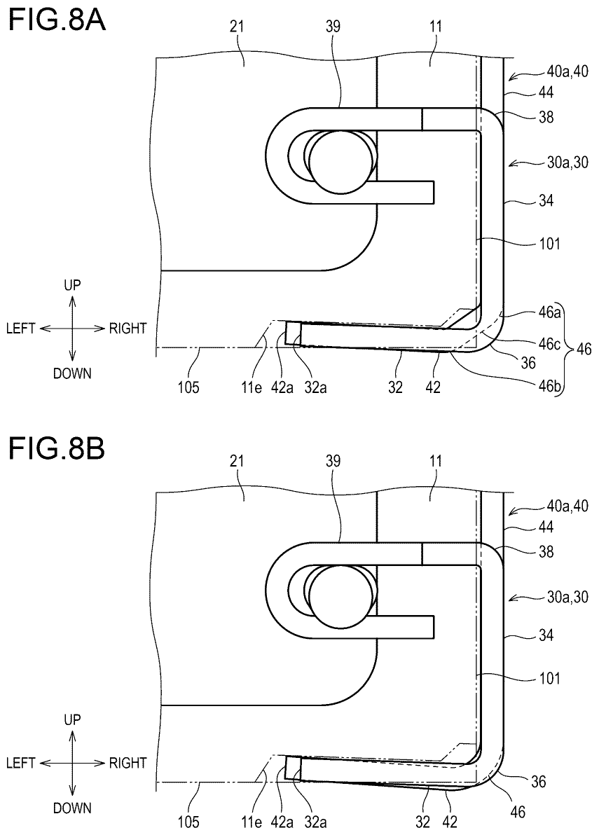

As illustrated in FIG. 8A, the second terminal 40 is bent at two locations (bending points 46a, 46b) in a first bent portion 46.

Due to the second terminal 40 being bent in multiple stages in the first bent portion 46, even if a crack occurs in the solder joining the second terminal 40 and the mounting substrate, the crack is more likely to stop at in a vicinity of the bending points 46a, 46b. In addition, due to the second terminal 40 extending in a plurality of directions in the first bent portion 46, the joint between the second terminal 40 and solder becomes more favorable. Note that in FIGS. 8A and 8B, a bending shape in the first bent portion 46 of the second terminal 40 is illustrated exaggerated compared to the actual shape. In reality, the bending shape in the first bent portion 46 of the second terminal 40 may be a shape resembling the bending shape in the first bent portion 36 in the first terminal 30.

The bending points 46a, 46b are center of portions that bend particularly sharply in the first bent portion 46. In other words, the first bent portion 46 of the second terminal 40 has a portion with a smaller radius of curvature than other portions (portions in a vicinity of the bending points 46a, 46b such as an intermediate portion 46c) (a portion that bends more sharply than others) at two locations. Centers of bending or portions including a vicinity of the centers at the two locations are the bending points 46a, 46b.

The two bending points 46a, 46b are separated from each other. The intermediate portion 46c sandwiched between the bending points 46a, 46b that are separated from each other has a more linear shape or a larger curved shape than the bending points 46a, 46b and vicinities thereof.

In the present embodiment, the radius of curvature of the second terminal 40 at the distal end-side bending point 46b is smaller than the radius of curvature of the second terminal 40 at the base end-side bending point 46a. In other words, the second terminal 40 is bent more sharply at the distal end-side bending point 46b than at the base end-side bending point 46a. Accordingly, a larger mounting surface that is a flat surface in the mounting portion 42 can be secured. As a result, a joint between the mounting portion 42 and the mounting substrate becomes favorable. Instead of the present embodiment, the radius of curvature of the second terminal 40 at the distal end-side bending point 46b may be larger than the radius of curvature of the second terminal 40 at the base end-side bending point 46a. In other words, the second terminal 40 may be bent in a larger curved shape at the distal end-side bending point 46b than at the base end-side bending point 46a. Accordingly, a stress applied on the second terminal 40 at the distal end-side bending point 46b can be favorably alleviated.

In the present embodiment, a bending angle of the second terminal 40 at the distal end-side bending point 46b is larger than a bending angle of the second terminal 40 at the base end-side bending point 46a. In other words, a minimum angle formed between an approximate extension direction of the intermediate portion 46c and the extension direction of the mounting portion 42 is smaller than a minimum angle formed between the approximate extension direction of the intermediate portion 46c and the erected portion 34. Due to such a configuration, the intermediate portion 46c is inclined at an angle smaller than 45 degrees relative to the horizontal. As a result, since the intermediate portion 46c is arranged to better extend along the mounting substrate, thereby improving the joint between the intermediate portion 46c and the mounting substrate and enabling the inductor assembly 100 to be more securely fixed by the mounting substrate.

In the present embodiment, the first terminal 30 is bent at one location in the first bent portion 36. Instead of the present embodiment, the first terminal 30 may be bent at two or more locations in the first bent portion 36.

In the present embodiment, the first bent portion 46 of the second terminal 40 is in closer proximity to the first core 11 than the first bent portion 36 of the first terminal 30. More specifically, when viewed in the arrangement direction of the first terminal 30 and the second terminal 40 (front-rear direction), the intermediate portion 46c is in closer proximity to the first core 11 than the center of bending of the first bent portion 36 of the first terminal 30. Accordingly, the second terminal 40 is bent so as to better extend along the first core 11 in the first bent portion 46. As a result, the second terminal 40 can more favorably hold the first core 11. When the second terminal 40 is curved more largely than the first terminal 30 without having the two or more bending points 46a, 46b as will be described later, the center of bending of the first bent portion 46 of the second terminal 40 is in closer proximity to the first core 11 than the center of bending of the first terminal 30.

Instead of the present embodiment, as illustrated in FIG. 8B, the radius of curvature of the first bent portion 46 of the second terminal 40 may be greater than the radius of curvature of the first bent portion 36 of the first terminal 30 that is arranged side by side with respect to the second terminal 40.

For example, a bending shape of the first terminal 30 or the second terminal 40 may be formed as described above by applying forces of different magnitudes or by applying stress to different portions of the terminals, respectively, when bending the first terminal 30 or the second terminal 40 at the first bent portions 36, 46.

Stress applied to the second terminal 40 can be more favorably alleviated by not bending the second terminal 40 more sharply than the first terminal 30. Therefore, the second terminal 40 is more securely fixed by the mounting substrate. In addition, compared to a space between the first terminal 30 and the mounting substrate, a larger space is created between the first bent portion 46 of the second terminal 40 with a larger radius of curvature and the mounting substrate. Therefore, since more solder can accumulate between the second terminal 40 and the mounting substrate, the second terminal 40 and the mounting substrate can be joined more securely. Accordingly, the second terminal 40 that is more prone to load than the first terminal 30 can be more securely fixed to the mounting substrate.

The second terminal 40 may be bent into a perfect circular arc shape in the first bent portion 46 or bent into a curved shape without a constant radius of curvature such as an elliptical arc shape.

The radius of curvature of the first bent portion 46 of the second terminal 40 being larger than the first bent portion 36 of the first terminal 30 means that, for example, a maximum value of the radius of curvature of the first bent portion 46 of the second terminal 40 is larger than the radius of curvature of the first bent portion 36 of the first terminal 30. Alternatively, the radius of curvature of the distal end or the base end of the first bent portion 46 in the second terminal 40 may be larger than the radius of curvature of the distal end or the base end of the first bent portion 36 in the first terminal 30. Alternatively, a distance between the base end and the distal end of the first bent portion 46 of the second terminal 40 (distance between the base end and the distal end on a straight line connecting the base end and the distal end) may be greater than a distance between the base end and the distal end of the first bent portion 36 of the first terminal 30.

In addition, the radius of curvature in the distal end portion of the first bent portion 46 of the second terminal 40 is preferably larger than the radius of curvature in the base end portion of the first bent portion 46. Accordingly, since the first bent portion 46 of the second terminal 40 is arranged so as to better extend along the mounting substrate, the joint between the first bent portion 46 and the mounting substrate can be made more favorable.

As illustrated in FIG. 8A, the angle formed between the erected portion 44 and the mounting portion 42 in the first bent portion 46 of the second terminal 40 is smaller than the angle formed between the erected portion 34 and the mounting portion 32 in the first bent portion 36 of the first terminal 30 that is arranged side by side with respect to the second terminal 40. In other words, the mounting portion 42 of the second terminal 40 may be inclined at a larger inclination angle relative to the lateral direction (or the bottom surface 105 of the inductor assembly 100) than the mounting portion 32 of the first terminal 30. The inclination angles of the mounting portions 32, 42 relative to the lateral direction refer to minimum angles formed between the lateral direction and the mounting portions 32, 42.

Instead of the present embodiment, the angle formed between the erected portion 44 and the mounting portion 42 in the first bent portion 46 of the second terminal 40 may be larger than the angle formed between the erected portion 34 and the mounting portion 32 in the first bent portion 36 of the first terminal 30 that is arranged side by side with respect to the second terminal 40.

As illustrated in FIG. 8A or 8B, in the present embodiment, the distal end 42a of the second terminal 40 is arranged above the distal end 32a of the first terminal 30. More specifically, the distal end 42a of the second terminal 40 is arranged in closer proximity to the first core 11 (in particular, the ceiling surface of the terminal recessed portion 11e) than the distal end 32a of the first terminal 30. In other words, the inclination angle of the mounting portion 42 of the second terminal 40 relative to the lateral direction is larger than the inclination angle of the ceiling surface of the terminal recessed portion 11e relative to the lateral direction. In addition, as described above, the inclination angle of the mounting portion 42 of the second terminal 40 relative to the lateral direction is larger than the inclination angle of the mounting portion 32 of the first terminal 30 relative to the lateral direction. Accordingly, the second terminal 40 can more favorably hold the first core 11. Note that the inductor assembly 100 need only be configured as described above in a natural state before the inductor assembly 100 is mounted to the mounting substrate. The first terminal 30 and the second terminal 40 need not be configured as described above when the inductor assembly 100 is mounted to the mounting substrate.

In addition, in the present embodiment, at least the distal ends 32a, 42a (or distal end portions including vicinities of the distal ends 32a, 42a) of each of the first terminal 30 and the second terminal 40 are arranged inside the terminal recessed portion 11e. In other words, the distal ends 32a, 42a or distal end portions of each of the first terminal 30 and the second terminal 40 are arranged above the bottom surface 105 (bottommost surface) of the first core 11. Instead of the present embodiment, the distal end 32a or the distal end portion of the first terminal 30 or the distal end 42a or the distal end portion of the second terminal 40 may protrude downward from the bottom surface 105 (bottommost surface) of the inductor assembly 100.

In the present embodiment, a lowermost point of the first bent portion 46 of the second terminal 40 is positioned lower than a lowermost point of the first bent portion 36 of the first terminal 30. In other words, the first bent portion 46 of the second terminal 40 is arranged so as to be in closer proximity than the first bent portion 36 of the first terminal 30 when mounting the inductor assembly 100 to the mounting substrate. Note that the inductor assembly 100 need only be configured as described above in a natural state before the inductor assembly 100 is mounted to the mounting substrate. The first terminal 30 and the second terminal 40 need not be configured as described above when the inductor assembly 100 is mounted to the mounting substrate.

In addition, at least a part of the first bent portion 36 of the first terminal 30 and at least a part of the first bent portion 46 of the second terminal 40 are arranged so as to protrude downward from the bottom surface 105 (bottommost surface) of the inductor assembly 100. Instead of the present embodiment, a lowermost portion of the first bent portion 36 of the first terminal 30 or a lowermost portion of the first bent portion 46 of the second terminal 40 may be at a same height as the bottom surface 105 (bottommost surface) of the inductor assembly 100.

The distal end 42a of the mounting portion 42 of the second terminal 40 is in contact with the bottom surface 105 of the inductor assembly 100. In addition, the distal end 32a of the mounting portion 32 of the first terminal 30 is separated from the bottom surface 105 of the inductor assembly 100.

Due to the distal end 42a of the second terminal 40 being in contact with the bottom surface of the inductor assembly 100 (bottom surface of first core 11), the second terminal 40 can more favorably hold the first core 11 and the second core 12. In addition, due to the distal end 32a of the first terminal 30 being separated from the bottom surface 105 of the inductor assembly 100, the mounting portion 32 of the first terminal 30 has a spring property without interfering with the inductor assembly 100. Accordingly, since the mounting portion 32 of the first terminal 30 can deform so as to extend along the mounting substrate when mounting the inductor assembly 100 to the mounting substrate, the inductor assembly 100 can be favorably mounted to the mounting substrate.

The distal end 42a of the second terminal 40 may be in pressurized contact with the bottom surface 105 of the inductor assembly 100 (the distal end 42a may bias the bottom surface 105 upward) or the distal end 42a may simply be in abutment with the bottom surface 105 of the inductor assembly 100. In addition, the distal end 42a of the second terminal 40 may be fitted into the first core 11. In other words, the distal end 42a and a vicinity thereof (a distal end portion including the distal end 42a) of the second terminal 40 may be arranged in an envelope body of the first core 11. Due to the distal end portion of the mounting portion 42 being embedded in the first core 11, the second terminal 40 can more favorably hold the first core 11.

As illustrated in FIG. 5, the radius of curvature of the second bent portion 48 of the second terminal 40 is smaller than the radius of curvature of the second bent portion 38 of the first terminal 30 that is arranged side by side with respect to the second terminal 40. Specifically, in the second bent portion 48, the second terminal 40 is sharply bent at a right angle while substantially coming into contact with the side surfaces 12a, 12c of the second core 12 (bent so as to closely extend along the side surfaces 12a, 12c of the second core 12). In contrast, the second bent portion 38 of the first terminal 30 slightly protrudes outward from the side surfaces 11a, 11c of the first core 11 and then gradually curves toward the side surfaces 11a, 11c. In other words, a gap between the second bent portion 48 of the second terminal 40 and the side surfaces 12a, 12c of the second core 12 is smaller than a gap between the second bent portion 38 of the first terminal 30 and the side surfaces 11a, 11c of the first core 11. Note that in FIG. 5, the difference between the radius of curvature in the second bent portion 48 of the second terminal 40 and the radius of curvature in the second bent portion 38 of the first terminal 30 is expressed large for the sake of convenience. In reality, the difference may be smaller than the illustrated difference. In addition, while the second bent portion 38 of the first terminal 30 protrudes further outside of the inductor assembly 100 than the second terminal 40 (in particular, the second bent portion 48 thereof), the second bent portion 38 of the first terminal 30 is not limited thereto. The second bent portion 38 of the first terminal 30 may be at a same position as the second bent portion 48 of the second terminal 40 in the left-right direction.

For example, a bending shape of the first terminal 30 or the second terminal 40 may be formed as described above by applying forces of different magnitudes or by applying stress to different portions of the terminals when bending the first terminal 30 or the second terminal 40 at the second bent portions 38, 48. In addition, in contrast to bending the second bent portion 38 of the first terminal 30 at a right angle or an angle exceeding a right angle, the second bent portion 48 of the second terminal 40 may be bent in advance at an acute angle (so that the erected portion 44 tapers inward and downward). Mounting the second terminal 40 bent at an acute angle in this manner in pressurized contact with a side surface of the core slightly widens the bending angle of the second bent portion 48 to a right angle and enables the erected portion 44 to extend along the side surface of the core while being in close contact with the side surface. As described above, due to the second terminal 40 being bent more sharply in the second bent portion 48, the second terminal 40 more favorably extends along the second core 12 (in particular, to a part in vicinity of the second bent portion 48). Accordingly, the second terminal 40 can more favorably hold the first core 11 and the second core 12.

The first terminal 30 and the second terminal 40 may be bent into a perfect circular arc shape in the second bent portions 38, 48 or bent into a curved shape without a constant radius of curvature such as an elliptical arc shape.

The radius of curvature of the second bent portion 38 of the first terminal 30 being larger than the second bent portion 48 of the second terminal 40 means that, for example, a maximum value of the radius of curvature of the second bent portion 38 of the first terminal 30 is larger than the radius of curvature of the second bent portion 48 of the second terminal 40. Alternatively, the radius of curvature of the distal end or the base end of the second bent portion 38 in the first terminal 30 may be larger than the radius of curvature of the distal end or the base end of the second bent portion 48 in the second terminal 40. Alternatively, a distance between the base end and the distal end of the second bent portion 38 of the first terminal 30 (distance between the base end and the distal end on a straight line connecting the base end and the distal end) may be greater than a distance between the base end and the distal end of the second bent portion 48 of the second terminal 40.

The present invention is not limited to the embodiments described above and includes aspects of various modifications, improvements, and the like insofar as the object of the present invention is achieved.

The modifications described below may be appropriately combined with one another.

The bending shape in the first bent portion 46 of the second terminal 40 is not limited to the shape described above. For example, the second terminal 40 may be bent at three or more locations in the first bent portion 46. In addition, the second terminal 40 may be bent in the first bent portion 46 so that a portion of or an entirety of the first bent portion 46 has a wave-like shape. When the first bent portion 46 of the second terminal 40 has a wave-like shape, a radius of curvature of a local curved portion that forms the wave-like shape may be adopted as the radius of curvature of the first bent portion 46 or a radius of curvature of an overall curved shape of the first bent portion 46 that ignores the wave-like shape may be adopted as the radius of curvature of the first bent portion 46.

Furthermore, a method of forming the bending shapes of the terminals and the like described in the present embodiment is not limited to the method described in the present embodiment. The bending shapes of the terminals and the like described in the present embodiment may be formed using methods other than that described in the present embodiment.

The embodiment described above covers the following technical ideas.
(1) An inductor assembly including a first core which encloses a first coil and a second core which is different from the first core and which encloses a second coil, wherein
   the second core is arranged above the first core,
   the inductor assembly has a plurality of side surfaces,
   each of the plurality of side surfaces in the inductor assembly includes a side surface of the first core and a side surface of the second core,
   each of a pair of first terminals electrically connected to the first coil
      protrudes from a side surface of the first core and
      has a mounting portion which extends along a bottom surface of the inductor assembly and an erected portion which is erected relative to the mounting portion,
   each of a pair of second terminals electrically connected to the second coil
      protrudes from a side surface of the second core and
      has a mounting portion which extends along the bottom surface and an erected portion which is erected relative to the mounting portion,
   the erected portion of one of the first terminals and the erected portion of one of the second terminals are formed on a first side surface among the side surfaces of the inductor assembly, and
   the pair of first terminals and the pair of second terminals are not formed on a second side surface of the inductor assembly which differs from the first side surface.
(2) The inductor assembly according to (1), wherein
   another of the first terminals and another of the second terminals are formed on a third side surface which opposes the first side surface among the side surfaces of the inductor assembly, and
   the pair of first terminals and the pair of second terminals are not formed on a fourth side surface which opposes the second side surface among the side surfaces of the inductor assembly.
(3) The inductor assembly according to (2), wherein
   on each of the first side surface and the third side surface, the first terminal and the second terminal are arranged side by side in an arrangement direction which is predetermined, and
   each of the one first terminal and the other first terminal is arranged on a same side in the arrangement direction relative to the one second terminal or the other second terminal.
(3-1) The inductor assembly according to (3), wherein a pair of the first terminals or a pair of the second terminals at least partially overlap each other when viewed from the side.
(4) The inductor assembly according to (3), wherein a distance between the first terminal and the second terminal arranged side by side in the arrangement direction on the first side surface or the third side surface is equal to or greater than a sum of a distance between an end portion in close proximity to the first terminals of the first side surface or the third side surface and the first terminals and a distance between an end portion in close proximity to the second terminals of the first side surface or the third side surface and the second terminals.
(4-1) The inductor assembly according to (4), wherein a difference between the distance between the first terminals and the second terminals and the sum of the distance between the end portion in close proximity to the first terminals and the first terminals and the distance between the end portion in close proximity to the second terminals and the second terminals is smaller than a width dimension of the first terminals or the second terminals.
(5) The inductor assembly according to (3) or (4), wherein the first terminal and the second terminal are bent so that the mounting portion is arranged below the inductor assembly in a first bent portion positioned between the erected portion and the mounting portion, and
   a distal end of the mounting portion of the second terminal is arranged further inside the inductor assembly than a distal end of the mounting portion of the first terminal which is arranged side by side with respect to the second terminals.
(5-1) The inductor assembly according to (5), wherein a distance between a distal end of the second terminals and a distal end of the first terminals in the extension direction of the mounting portion is equal to or greater than a thickness dimension of the first terminals or the second terminals.
(6) The inductor assembly according to (5), wherein the second terminal is bent at two locations in the first bent portion.
(6-1) The inductor assembly according to (6), wherein the first bent portion of the second terminals is in closer proximity to a first core than the first bent portion of the first terminals.
(6-2) The inductor assembly according to (6), wherein a radius of curvature of the second terminals at a distal end-side bending point of the second terminals is smaller than a radius of curvature of the second terminals at a base end-side bending point of the second terminals.
(6-3) The inductor assembly according to (6), wherein a bending angle of the second terminals at a distal end-side bending point is larger than a bending angle of the second terminals at a base end-side bending point.
(7) The inductor assembly according to (5), wherein a radius of curvature of the first bent portion of the second terminal is larger than a radius of curvature of the first bent portion of the first terminal arranged side by side with respect to the second terminal.
(7-1) The inductor assembly according to (7), wherein a radius of curvature in a distal end portion of the first bent portion of the second terminals is larger than a radius of curvature in a base end portion of the first bent portion.
(8) The inductor assembly according to any one of (5) to (7), wherein an angle formed between the erected portion and the mounting portion in the first bent portion of the second terminal is smaller than an angle formed between the erected portion and the mounting portion in the first bent portion of the first terminal arranged side by side with respect to the second terminal.
(9) The inductor assembly according to (8), wherein a distal end of the mounting portion of the second terminal is in contact with the bottom surface of the inductor assembly, and
   a distal end of the mounting portion of the first terminal is separated from the bottom surface of the inductor assembly.
(9-1) The inductor assembly according to (9), wherein a distal end of the second terminals is fitted into a first core.
(10) The inductor assembly according to any one of (3) to (9), wherein each of the first terminals and the second terminals is bent in a second bent portion positioned between an embedded portion that is embedded in the first core or the second core and the erected portion, and
   a radius of curvature of the second bent portion of the second terminal is smaller than a radius of curvature of the second bent portion of the first terminal arranged side by side with respect to the second terminals.
(11) An inductor assembly, wherein a distal end of a second terminal is arranged above a distal end of a first terminal.
(12) An inductor assembly, wherein a second bent portion of a second terminal is arranged below a first bent portion of a first terminal.
(13) An inductor assembly, wherein an upper portion in an erected portion of a second terminal is more largely curved toward a second core than a lower portion in an erected portion of a first terminal.

What is claimed is:

1. An inductor assembly comprising:
a first core which encloses a first coil; and
a second core which is different from the first core and which encloses a second coil, wherein
the second core is arranged above the first core,
the inductor assembly has a plurality of side surfaces,
each of the plurality of side surfaces in the inductor assembly includes a side surface of the first core and a side surface of the second core,
each of a pair of first terminals electrically connected to the first coil
protrudes from a side surface of the first core and
has a mounting portion which extends along a bottom surface of the inductor assembly and an erected portion which is erected relative to the mounting portion,
each of a pair of second terminals electrically connected to the second coil
protrudes from a side surface of the second core and
has a mounting portion which extends along the bottom surface and an erected portion which is erected relative to the mounting portion,
the erected portion of one of the first terminals and the erected portion of one of the second terminals are formed on a first side surface among the side surfaces of the inductor assembly, and
the pair of first terminals and the pair of second terminals are not formed on a second side surface of the inductor assembly which differs from the first side surface.

2. The inductor assembly according to claim 1, wherein
another of the first terminals and another of the second terminals are formed on a third side surface which opposes the first side surface among the side surfaces of the inductor assembly, and
the pair of first terminals and the pair of second terminals are not formed on a fourth side surface which opposes the second side surface among the side surfaces of the inductor assembly.

3. The inductor assembly according to claim 2, wherein
on each of the first side surface and the third side surface, the first terminal and the second terminal are arranged side by side in an arrangement direction which is predetermined, and
each of the one first terminal and the other first terminal is arranged on a same side in the arrangement direction relative to the one second terminal or the other second terminal.

4. The inductor assembly according to claim 3, wherein a distance between the first terminal and the second terminal arranged side by side in the arrangement direction on the first side surface or the third side surface is equal to or greater than a sum of a distance between an end portion in close proximity to the first terminals of the first side surface or the third side surface and the first terminals and a distance between an end portion in close proximity to the second terminals of the first side surface or the third side surface and the second terminals.

5. The inductor assembly according to claim 3, wherein the first terminal and the second terminal are bent so that the mounting portion is arranged below the inductor assembly in a first bent portion positioned between the erected portion and the mounting portion, and
a distal end of the mounting portion of the second terminal is arranged further inside the inductor assembly than a distal end of the mounting portion of the first terminal which is arranged side by side with respect to the second terminal.

6. The inductor assembly according to claim 5, wherein the second terminal is bent at two locations in the first bent portion.

7. The inductor assembly according to claim 5, wherein a radius of curvature of the first bent portion of the second terminal is larger than a radius of curvature of the first bent portion of the first terminal arranged side by side with respect to the second terminal.

8. The inductor assembly according to claim 5, wherein an angle formed between the erected portion and the mounting portion in the first bent portion of the second terminal is smaller than an angle formed between the erected portion and the mounting portion in the first bent portion of the first terminal arranged side by side with respect to the second terminal.

9. The inductor assembly according to claim 8, wherein a distal end of the mounting portion of the second terminal is in contact with the bottom surface of the inductor assembly, and
a distal end of the mounting portion of the first terminal is separated from the bottom surface of the inductor assembly.

10. The inductor assembly according to claim 3, wherein each of the first terminals and the second terminals is bent in a second bent portion positioned between an embedded portion that is embedded in the first core or the second core and the erected portion, and
a radius of curvature of the second bent portion of the second terminal is smaller than a radius of curvature of the second bent portion of the first terminal arranged side by side with respect to the second terminals.
